(19) United States
(12) Patent Application Publication
(10) Pub. No.: US 2026/0080915 A1
(43) Pub. Date: Mar. 19, 2026

(54) MEMORY DEVICE

(71) Applicant: Kioxia Corporation, Tokyo (JP)

(72) Inventor: Keisuke NAKATSUKA, Kuwana Mie (JP)

(73) Assignee: Kioxia Corporation, Tokyo (JP)

(21) Appl. No.: 19/074,321

(22) Filed: Mar. 8, 2025

(30) Foreign Application Priority Data
Sep. 19, 2024 (JP) 2024-162491

(51) Int. Cl. G11C 5/06; G11C 16/04; H10B 43/10; H10B 43/27; H10B 43/35

(52) U.S. Cl. CPC G11C 5/063; G11C 16/0483; H10B 43/10; H10B 43/27; H10B 43/35

(57) ABSTRACT

According to one embodiment, a memory device includes: a plurality of first conductive layers aligned apart from each other in a first direction; a first member extending in a second direction intersecting the first direction and dividing the first conductive layers into a first portion and a second portion aligned in a third direction intersecting the first direction and the second direction; a plurality of first memory pillars each extending in the first direction and intersecting with each of the first portions of the first conductive layers; and a plurality of second memory pillars each extending in the first direction and intersecting with each of the second portions of the first conductive layers. The second memory pillars are disposed to be deviated with respect to the first memory pillars in the second direction as viewed in the first direction.

### CROSS-REFERENCE TO RELATED APPLICATIONS

This application is based upon and claims the benefit of priority from Japanese Patent Application No. 2024-162491, filed Sep. 19, 2024, the entire contents of which are incorporated herein by reference.

### FIELD

Embodiments described herein relate generally to a memory device.

### BACKGROUND

A NAND flash memory is known as a memory device capable of storing data in a nonvolatile manner. In the memory device such as the NAND flash memory, a three-dimensional memory structure is adopted for enhanced integration and increased capacity.

### BRIEF DESCRIPTION OF DRAWINGS

FIG. 1 is a block diagram illustrating an example of a configuration of a memory system including a memory device according to an embodiment.

FIG. 2 is a circuit diagram illustrating an example of a circuit configuration of a memory cell array included in the memory device according to the embodiment.

FIG. 3 is a plan view illustrating an example of a planar layout of the memory cell array included in the memory device according to the embodiment.

FIG. 4 is a plan view illustrating an example of a planar layout in a memory region of the memory cell array according to the embodiment.

FIG. 5 is a cross-sectional view taken along line V-V in FIG. 4, and illustrating an example of a cross-sectional structure in the memory region of the memory cell array according to the embodiment.

FIG. 6 is a cross-sectional view taken along line VI-VI in FIG. 5, and illustrating an example of a cross-sectional structure of a memory pillar included in the memory cell array according to the embodiment.

FIG. 7 is a cross-sectional view taken along line VII-VII in FIG. 5, and illustrating an example of a cross-sectional structure of the memory pillar included in the memory cell array according to the embodiment.

FIG. 8 is a plan view illustrating an example of a planar layout in an adjustment region of the memory cell array according to the embodiment.

FIG. 9 is a diagram schematically illustrating an example of a connection relationship between a bit line and a memory pillar of a memory device according to a comparative example.

FIG. 10 is a diagram schematically illustrating an example of a connection relationship between a bit line and a memory pillar of the memory device according to the embodiment.

FIG. 11 is a diagram schematically illustrating an example of a connection relationship between a bit line and a memory pillar of a memory device according to a first modification.

FIG. 12 is a plan view illustrating an example of the planar layout of a memory cell array included in a memory device according to a second modification.

FIG. 13 is a plan view illustrating an example of the planar layout of a memory cell array included in a memory device according to a third modification.

### DETAILED DESCRIPTION

In general, according to one embodiment, a memory device includes: a plurality of first conductive layers aligned apart from each other in a first direction; a first member extending in a second direction intersecting the first direction and dividing the first conductive layers into a first portion and a second portion aligned in a third direction intersecting the first direction and the second direction; a plurality of first memory pillars each extending in the first direction and intersecting with each of the first portions of the first conductive layers; and a plurality of second memory pillars each extending in the first direction and intersecting with each of the second portions of the first conductive layers. The second memory pillars are disposed to be deviated with respect to the first memory pillars in the second direction as viewed in the first direction.

Hereinafter, an embodiment will be described with reference to the drawings. The dimensions and ratios of the drawings are not necessarily the same as those of actual products.

In the following description, components having substantially the same functions and configurations are denoted by the same reference numerals. To particularly distinguish between elements having the same configurations, characters or numbers different from each other may be added to the ends of the same reference numerals.

### 1. EMBODIMENT

### 1.1 Configuration

### 1.1.1 Configuration of Memory System

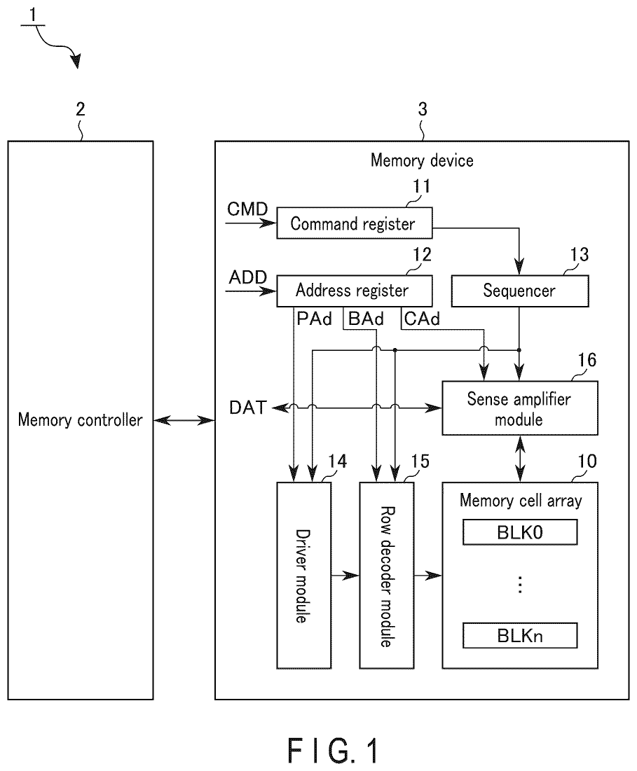

FIG. 1 is a block diagram illustrating an example of a configuration of a memory system including a memory device according to an embodiment. A memory system 1 is a memory device configured to be connected to an external host (not illustrated). The memory system 1 is, for example, a memory card such as an SD™ card, a universal flash storage (UFS), and a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host into the memory device 3. The memory controller 2 reads data requested to be read from the host from the memory device 3 and transmits the data to the host.

The memory device 3 is a nonvolatile memory. The memory device 3 is, for example, a NAND flash memory. The memory device 3 stores data in a nonvolatile manner.

Communication between the memory controller 2 and the memory device 3 conforms to, for example, a single data rate (SDR) interface, a toggle double data rate (DDR) interface, or an open NAND flash interface (ONFI).

### 1.1.2 Configuration of Memory Device

Subsequently, the internal configuration of the memory device according to the embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The number of blocks BLK included in the memory cell array 10 may be one. The block BLK is a set of memory cells. The block BLK is used, for example, as a data erasing unit. A plurality of bit lines and a plurality of word lines are provided in the memory cell array 10. Each memory cell is associated with, for example, one bit line and one word line. The configuration of the memory cell array 10 will be described in detail later.

The command register 11 stores a command CMD received by the memory device 3 from the memory controller 2. The command CMD includes, for example, instructions for causing the sequencer 13 to execute a read operation, a write operation, an erase operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls the entire operation of the memory device 3. For example, the sequencer 13 controls the driver module 14, the row decoder module 15, the sense amplifier module 16, and the like to execute a read operation, a write operation, an erase operation, and the like based on the command CMD memorized in the command register 11.

The driver module 14 generates voltages used in each of the read operation, the write operation, the erase operation, and the like. The driver module 14 applies the generated voltage to a signal line corresponding to the selected word line based on, for example, the page address PAd stored in the address register 12.

The row decoder module 15 selects one block BLK in the corresponding memory cell array 10 based on the block address BAd stored in the address register 12. The row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In the read operation, the sense amplifier module 16 determines the data stored in the memory cell based on the voltage of the bit line, and transfers the determination result to the memory controller 2 as read data DAT.

### 1.1.3 Circuit Configuration of Memory Cell Array

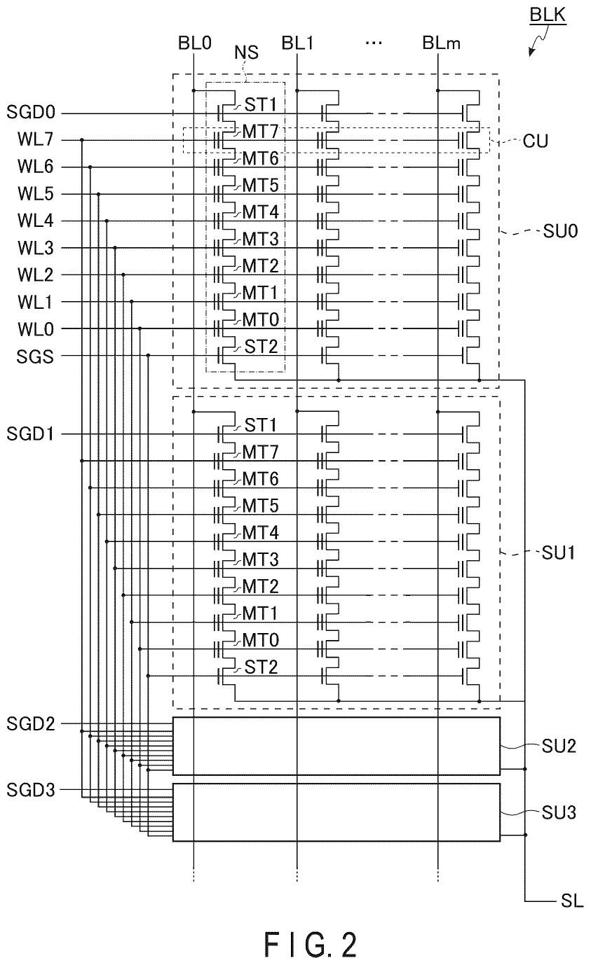

FIG. 2 is a circuit diagram illustrating an example of a circuit configuration of a memory cell array included in the memory device according to the embodiment. FIG. 2 illustrates one block BLK among the plurality of blocks BLK included in the memory cell array 10. As illustrated in FIG. 2, the block BLK includes, for example, four string units SU0 to SU3.

Each string unit SU includes a plurality of NAND strings NS associated with bit lines BL0 to BLm (m is an integer of 1 or more). The number of the bit lines BL may be one. Each NAND string NS includes, for example, memory cell transistors MT0 to MT7 and select transistors ST1 and ST2. Each memory cell transistor MT includes a control gate and a charge storage portion, and stores data in a nonvolatile manner. Each of the select transistors ST1 and ST2 is used to select the string unit SU during various operations.

In each NAND string NS, the memory cell transistors MT0 to MT7 are connected in series. The drain of the select transistor ST1 is connected to the associated bit line BL. The source of the select transistor ST1 is connected to one end of the memory cell transistors MT0 to MT7 connected in series. The drain of the select transistor ST2 is connected to the other end of the memory cell transistors MT0 to MT7 connected in series. The source of the select transistor ST2 is connected to a source line SL.

In the same block BLK, the control gates of the memory cell transistors MT0 to MT7 are connected to word lines WL0 to WL7, respectively. The gates of the select transistors ST1 in the string units SU0 to SU3 are connected to select gate lines SGD0 to SGD3, respectively. The gates of the plurality of select transistors ST2 are connected to a select gate line SGS.

Column addresses different from each other are allocated to the bit lines BL0 to BLm. Each bit line BL is shared by the NAND string NS to which the same column address is allocated among the plurality of blocks BLK. Each of the word lines WL0 to WL7 is provided for each block BLK. The source line SL is shared among the plurality of blocks BLK, for example.

A set of the plurality of memory cell transistors MT connected to a common word line WL in one string unit SU is referred to as, for example, a cell unit CU. For example, the memory capacity of the cell unit CU including the memory cell transistors MT each storing 1-bit data is defined as “1-page data”. The cell unit CU may have a memory capacity of 2-page data or more according to the number of bits of data stored in the memory cell transistor MT.

Note that the circuit configuration of the memory cell array 10 included in the memory device 3 according to the embodiment is not limited to the configuration described above. For example, the number of string units SU included in each block BLK may be discretionarily designed. The numbers of the memory cell transistors MT and the select transistors ST1 and ST2 included in each NAND string NS may be discretionarily designed.

### 1.1.4 Structure of Memory Cell Array

Next, an example of the structure of a memory cell array included in the memory device according to the embodiment will be described. In the drawings referred to below, an X direction corresponds to the extending direction of the word line WL. A Y direction corresponds to the extending direction of the bit line BL. A Z direction corresponds to the stacking direction of the word line WL and the bit line BL. In the plan view, hatching is appropriately added to make the drawing easy to see. The hatching added to the plan view is not necessarily related to the materials or characteristics of components to which the hatching is added. In the cross-sectional view, the illustration of the configuration is appropriately omitted in order to make the view easy to see.

### 1.1.4.1 Overall Planar Layout of Memory Cell Array

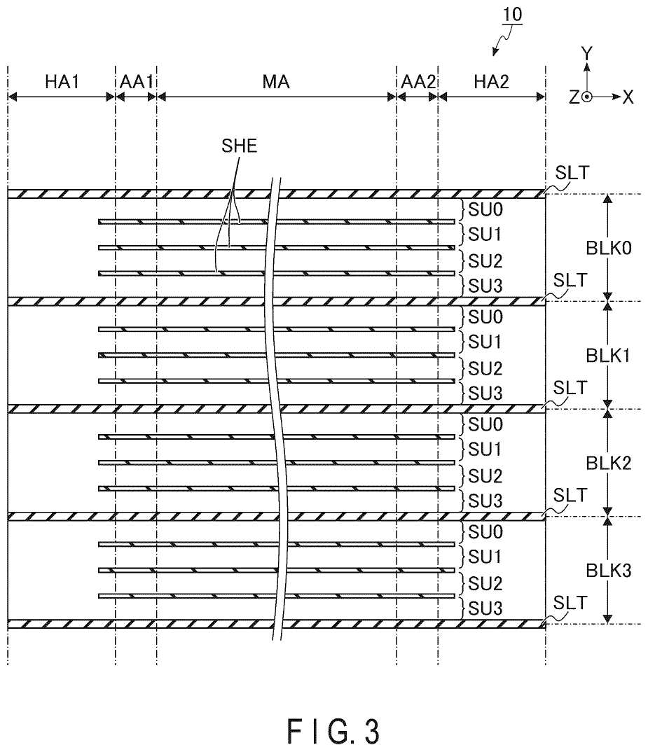

FIG. 3 is a plan view illustrating an example of a planar layout of the memory cell array included in the memory device according to the embodiment. In FIG. 3, regions corresponding to four blocks BLK0 to BLK3 are illustrated. As illustrated in FIG. 3, the planar layout of the memory cell array 10 is divided into, for example, a memory region MA, adjustment regions AA1 and AA2, and hookup regions HA1 and HA2 in the X direction. The memory cell array 10 includes a stacked wiring structure and a plurality of members SLT and SHE.

The stacked wiring structure has a structure in which stacked wirings including the word lines WL0 to WL7 and the select gate lines SGD and SGS are stacked in the Z direction. The stacked wiring structure is provided over the memory region MA, the adjustment regions AA1 and AA2, and the hookup regions HA1 and HA2.

The memory region MA is disposed, for example, in a central portion of the memory cell array 10. The memory region MA is a region including a plurality of NAND strings NS.

The adjustment regions AA1 and AA2 are disposed so as to sandwich the memory region MA in the X direction. A plurality of NAND strings NS are provided in the adjustment regions AA1 and AA2 similarly to the memory region MA. The adjustment regions AA1 and AA2 are regions for adjusting a disposing deviation (to be described later) in the X direction of the NAND string NS occurring between the blocks BLK in the memory region MA. The disposing deviation of the NAND string NS adjusted in the adjustment regions AA1 and AA2 is resolved before reaching the hookup regions HA1 and HA2.

The hookup regions HA1 and HA2 are disposed so as to sandwich the adjustment region AA1, the memory region MA, and the adjustment region AA2 in the X direction. In the example of FIG. 3, a case where the hookup region HA1, the adjustment region AA1, the memory region MA, the adjustment region AA2, and the hookup region HA2 are aligned in this order in the X direction is illustrated. Each of the hookup regions HA1 and HA2 is a region used for connection between the stacked wiring (that is, the word lines WL0 to WL7 and the select gate lines SGD and SGS) included in the stacked wiring structure and the row decoder module 15.

The plurality of members SLT are aligned in the Y direction. Each of the plurality of members SLT extends in the X direction so as to traverse the memory region MA, the adjustment regions AA1 and AA2, and the hookup regions HA1 and HA2. Each of the plurality of members SLT has, for example, a structure in which an insulator and a plate-like contact is embedded. Each of the plurality of members SLT separates the stacked wiring in the Y direction.

The plurality of members SHE are aligned in the Y direction. In the present example, three members SHE are disposed between any two adjacent members SLT in the Y direction. Each of the plurality of members SHE extends in the X direction so as to traverse the memory region MA and the adjustment regions AA1 and AA2. Both the ends of each of the plurality of members SHE are located in the hookup regions HA1 and HA2, respectively. Each of the plurality of members SHE has, for example, a structure in which an insulator is embedded. Each of the plurality of members SHE selectively separates the select gate line SGD among the stacked wirings.

In the planar layout of the memory cell array 10 described above, each portion of the stacked wiring structure divided by any two adjacent members SLT in the Y direction corresponds to one block BLK. In the stacked wiring structure, each of portions divided by members SLT and SHE adjacent to each other in the Y direction or any two adjacent members SHE in the Y direction corresponds to one string unit SU. In the memory cell array 10, for example, the planar layout illustrated in FIG. 3 is repeatedly disposed in the Y direction.

The planar layout of the memory cell array 10 included in the memory device 3 according to the embodiment is not limited to the above example. For example, the number of the members SHE disposed between any two adjacent members SLT in the Y direction may be discretionarily designed. The number of the string units SU formed between any two adjacent members SLT in the Y direction may be changed according to the number of the members SHE disposed between any two adjacent members SLT in the Y direction.

### 1.1.4.2 Planar Layout of Memory Region

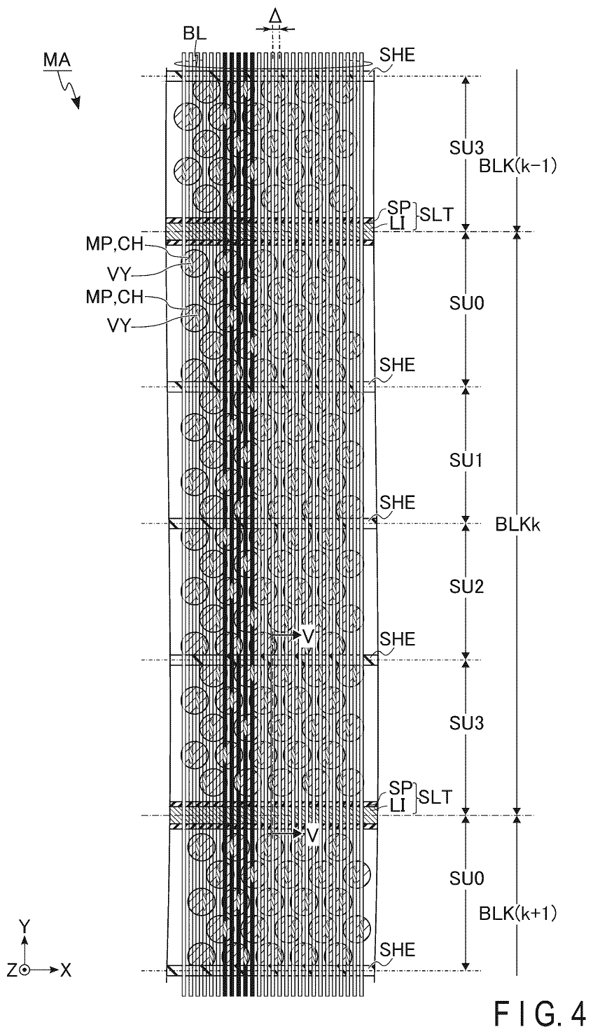

FIG. 4 is a plan view illustrating an example of a planar layout in a memory region of the memory cell array according to the embodiment. FIG. 4 illustrates one block BLKk (string units SU0 to SU3), a part of two blocks BLK (k−1) adjacent to the block BLKk (string unit SU3), and a part of the block BLK (k+1) (string unit SU0). As illustrated in FIG. 4, in the memory region MA, the memory cell array 10 includes a plurality of memory pillars MP, a plurality of contacts CH and VY, and a plurality of bit lines BL. Each of the plurality of members SLT includes a contact LI and a spacer SP.

The contact LI is a conductor extending in the XZ plane. The spacer SP is an insulator provided on the side surface of the contact LI. In other words, the contact LI is surrounded by the spacers SP in plan view.

Each of the memory pillars MP functions as, for example, one NAND string NS. The plurality of memory pillars MP are disposed in, for example, twenty rows in a staggered manner in a region between any two adjacent members SLT in the Y direction. Among the twenty rows of memory pillars MP, the first to fifth rows of memory pillars MP correspond to the string unit SU0. The sixth to tenth rows of memory pillars MP correspond to the string unit SU1. The 11th to 15th rows of memory pillars MP correspond to the string unit SU2. The 16th to 20th rows of memory pillars MP correspond to the string unit SU3. For example, the first member SHE overlaps with the fifth row and sixth row of memory pillars MP counted from the upper side of the plane of paper. The second member SHE overlaps with the tenth row and 11th row of memory pillars MP counted from the upper side of the plane of paper. The third member SHE overlaps with the 15th row and 16th row of memory pillars MP counted from the upper side of the plane of paper.

The plurality of bit lines BL are aligned in the X direction. Each of the plurality of bit lines BL extends in the Y direction. Each of the plurality of bit lines BL is disposed so as to overlap with at least one memory pillar MP in plan view for each string unit SU. Each of the plurality of bit lines BL is electrically connected to a corresponding memory pillar MP of at least one memory pillar MP overlapping in plan view via a set of contacts CH and VY for each string unit SU.

In the example of FIG. 4, a case where the five bit lines BL aligned adjacent to each other in the X direction are electrically connected to the five rows of memory pillars MP in the same string unit SU is illustrated. More specifically, for example, in the block BLKk, the first bit line BL among the five bit lines BL painted black in FIG. 4 is electrically connected to the first, ninth, eleventh, and nineteenth rows of memory pillars MP. The second bit line BL is electrically connected to the third, seventh, thirteenth, and seventeenth rows of memory pillars MP. The third bit line BL is electrically connected to the fifth, tenth, fifteenth, and twentieth rows of memory pillars MP. The fourth bit line BL is electrically connected to the second, eighth, twelfth, and eighteenth rows of memory pillars MP. The fifth bit line BL is electrically connected to the fourth, sixth, fourteenth, and sixteenth rows of memory pillars MP.

The layout of the memory pillars MP described above is shifted in the X direction by a pitch Δ between the bit lines BL between the adjacent blocks BLK. In the example of FIG. 4, the layout of the memory pillars MP in the block BLK (k−1) is shifted in the −X direction by the pitch Δ with respect to the layout of the memory pillars MP in the block BLKk. That is, the amount of deviation of the layout of the memory pillars MP of the block BLK (k−1) with respect to the block BLKk is −Δ. Therefore, in the block BLK (k−1), the first bit line BL among the five bit lines BL painted black in FIG. 4 is electrically connected to the (third, seventh, thirteenth, and) seventeenth rows of memory pillars MP. The second bit line BL is electrically connected to the (fifth, tenth, fifteenth and) twentieth rows of memory pillars MP. The third bit line BL is electrically connected to the (second, eighth, twelfth, and) eighteenth rows of memory pillars MP. The fourth bit line BL is electrically connected to the (fourth, sixth, fourteenth, and) sixteenth rows of memory pillars MP. The fifth bit line BL is electrically connected to the (first, ninth, eleventh and) nineteenth rows of memory pillars MP.

The layout of the memory pillars MP in the block BLK (k+1) is shifted in the +X direction by the pitch Δ with respect to the layout of the memory pillars MP in the block BLKk. That is, the amount of deviation of the layout of the memory pillars MP of the block BLK (k+1) with respect to the block BLKk is +Δ. Therefore, in the block BLK (k+1), the first bit line BL among the five bit lines BL painted black in FIG. 4 is electrically connected to the fourth (sixth, fourteenth, and sixteenth) rows of memory pillars MP. The second bit line BL is electrically connected to the first (ninth, eleventh, and nineteenth) rows of memory pillars MP. The third bit line BL is electrically connected to the third (seventh, thirteenth, and seventeenth) rows of memory pillars MP. The fourth bit line BL is electrically connected to the fifth (tenth, fifteenth, and twentieth) rows of memory pillars MP. The fifth bit line BL is electrically connected to the second (eighth, twelfth, and eighteenth) rows of memory pillars MP.

### 1.1.4.3 Cross-Sectional Structure of Memory Region

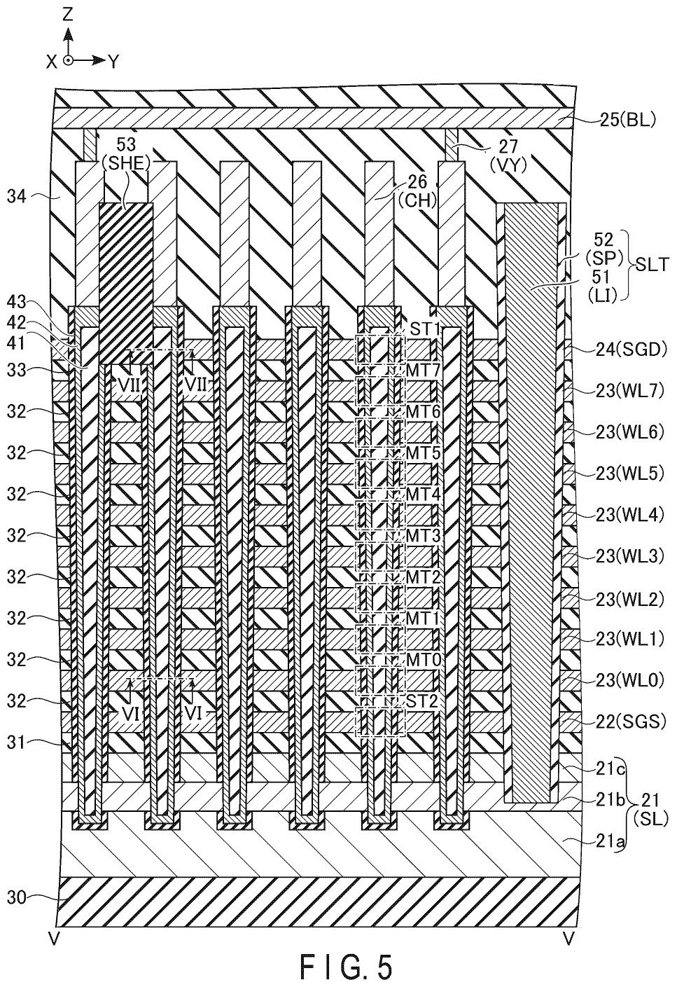

FIG. 5 is a cross-sectional view taken along line V-V in FIG. 4, and illustrating an example of a cross-sectional structure in the memory region of the memory cell array according to the embodiment. As illustrated in FIG. 5, the memory cell array 10 further includes a semiconductor layer 21, conductive layers 22, 23, 24, and 25, conductive films 26, 27, and 51, insulating layers 30, 31, 32, 33, and 34, a core film 41, a semiconductor film 42, a stacked film 43, and insulating films 52 and 53.

The semiconductor layer 21 is provided on an upper surface of the insulating layer 30. The semiconductor layer 21 includes, for example, three semiconductor layers 21a, 21b, and 21c. The semiconductor layer 21b is provided on an upper surface of the semiconductor layer 21a. The semiconductor layer 21c is provided on an upper surface of the semiconductor layer 21b. The semiconductor layer 21b is formed, for example, by replacing a insulating layer provided between the semiconductor layer 21a and the semiconductor layer 21c. The semiconductor layers 21a to 21c contain, for example, polysilicon. The semiconductor layers 21a to 21c contain, for example, phosphorus (P) as a semiconductor impurity.

The insulating layer 31 and the conductive layer 22 are alternately stacked one by one on an upper surface of the semiconductor layer 21c. The conductive layer 22 is formed in, for example, a plate shape extending in the XY plane. The conductive layer 22 is used as the select gate line SGS. The conductive layer 22 contains, for example, tungsten.

The eight insulating layers 32 and the eight conductive layers 23 are alternately stacked one by one on an upper surface of the conductive layer 22. Each of the plurality of conductive layers 23 is formed in, for example, a plate shape extending in the XY plane. The plurality of conductive layers 23 are used as the word lines WL0 to WL7, respectively. Each of the plurality of conductive layers 23 contains, for example, tungsten.

The insulating layer 33 and the conductive layer 24 are alternately stacked one by one on the upper surface of an conductive layer 23 as the uppermost layer. The conductive layer 24 is formed in, for example, a plate shape extending in the XY plane. The conductive layer 24 is used as the select gate line SGD. The conductive layer 24 contains, for example, tungsten.

The conductive layer 25 is provided above the conductive layer 24 with the insulating layer 34 interposed therebetween. The conductive layer 25 is formed in a line shape extending in the Y direction. The conductive layer 25 is used as the bit line BL. That is, in a region (not illustrated), the plurality of conductive layers 25 are aligned in the X direction. The conductive layer 25 contains, for example, copper.

The member SLT includes the conductive film 51 and the insulating film 52. The conductive film 51 is formed in a plate shape extending in the XZ plane. The conductive film 51 contains, for example, tungsten and is used as the contact LI. A lower end of the conductive film 51 is located in the semiconductor layer 21b. An upper end of the conductive film 51 is located above the conductive layer 24.

The insulating film 52 is formed in a plate shape extending in the XZ plane. The insulating film 52 contains, for example, silicon oxide and is used as the spacer SP. The insulating film 52 divides the plurality of conductive layers 22, 23, and 24 in the Y direction. The insulating film 52 is provided so as to cover a side surface of the conductive film 51, and electrically insulates the plurality of conductive layers 22, 23, and 24 from the conductive film 51.

The member SHE includes the insulating film 53. The insulating film 53 is formed in a plate shape extending in the XZ plane. The insulating film 53 contains, for example, silicon oxide. The insulating film 53 divides the conductive layer 24 in the Y direction. A lower end of the insulating film 53 is located in the insulating layer 33 between the conductive layer 24 and the conductive layer 23 as the uppermost layer. An upper end of the insulating film 53 is located above the conductive layer 24.

The memory pillar MP has a substantially cylindrical shape extending in the Z direction. The memory pillar MP penetrates the plurality of conductive layers 22, 23, and 24. A bottom surface of the memory pillar MP reaches the semiconductor layer 21a. The conductive film 26 is provided on an upper surface of the semiconductor film 42 of the memory pillar MP. The conductive film 26 is formed in a columnar shape extending in the Z direction and is used as the contact CH.

The conductive film 27 is provided on an upper surface of the conductive film 26. The conductive film 27 is formed in a columnar shape extending in the Z direction and is used as the contact VY. In FIG. 5, two contacts VY corresponding to the two memory pillars MP (the first and sixth memory pillars MP from the right side of the plane of paper in FIG. 5) among the six memory pillars MP aligned in the Y direction are illustrated. In FIG. 5, the corresponding contact VY is connected to the memory pillar MP to which the contact VY is not connected in a region (not illustrated).

On an upper surface of the contact VY, one conductive layer 25, that is, one bit line BL is provided. One conductive layer 25 is in contact with one contact VY in each of a space divided by the members SLT and SHE and a space divided by the two members SHE.

Next, the structure of the memory pillar MP will be described. The memory pillar MP includes a core film 41, a semiconductor film 42, and a stacked film 43.

The core film 41 extends in the Z direction. The core film 41 includes, for example, an insulator such as silicon oxide. An upper end of the core film 41 reaches the insulating layer 34, and a lower end of the core film 41 reaches the semiconductor layer 21a.

The semiconductor film 42 covers the circumference of the core film 41. The semiconductor film 131 contains, for example, silicon. At a lower end of the memory pillar MP, a part of the semiconductor film 42 is in contact with the semiconductor layer 21b.

The stacked film 43 covers a side surface and lower end of the semiconductor film 42 except for a portion where the semiconductor film 42 and the semiconductor layer 21b are in contact with each other.

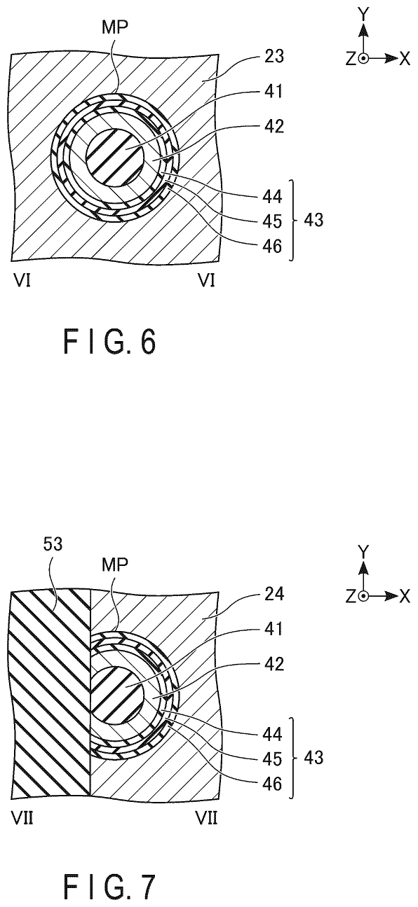

FIG. 6 is a cross-sectional view taken along line VI-VI of FIG. 5, and illustrating an example of a cross-sectional structure of a memory pillar included in the memory cell array according to the embodiment. FIG. 6 illustrates the cross-sectional structure of a memory pillar MP in a layer parallel to the XY plane and including the conductive layer 23 as the lowermost layer. As illustrated in FIG. 6, the stacked film 43 includes, for example, a tunnel insulating film 44, a charge storage film 45, and a block insulating film 446.

In the cross section including the conductive layer 23, the core film 41 is provided, for example, at a central portion of the memory pillar MP. The semiconductor film 42 surrounds a side surface of the core film 41. The tunnel insulating film 44 surrounds a side surface of the semiconductor film 42. The charge storage film 45 surrounds a side surface of the tunnel insulating film 44. The block insulating film 46 surrounds a side surface of the charge storage film 45. The conductive layer 23 surrounds a side surface of the block insulating film 46. Each of the tunnel insulating film 44 and the block insulating film 46 contains, for example, silicon oxide. The charge storage film 45 has a function of accumulating charges, and contains, for example, silicon nitride.

The memory pillar MP and the conductive layer 23 functioning as the word lines WL0 to WL7 are combined to form the memory cell transistors MT0 to MT7. Similarly, the memory pillar MP and the conductive layer 24 functioning as the select gate line SGD are combined to form the select transistor ST1. The memory pillar MP and the conductive layer 22 functioning as the select gate line SGS are combined to form the select transistor ST2. As a result, each memory pillar MP can function as one NAND string NS.

Among the plurality of memory pillars MP, the memory pillars MP in contact with the member SHE (the fifth and sixth memory pillars MP from the right side of the plane of paper in FIG. 5) have a shape in which a part of the memory pillar MP is chipped by the member SHE.

FIG. 7 is a cross-sectional view taken along line VII-VII of FIG. 5, and illustrating an example of a cross-sectional structure of a memory pillar included in the memory cell array according to the embodiment. FIG. 7 illustrates the cross-sectional structure of a memory pillar MP in a layer parallel to the XY plane and including the conductive layer 24. As illustrated in FIG. 7, in the layer including the conductive layer 24, the semiconductor film 42 surrounds a portion of the side surface of the core film 41 excluding a contact surface with the insulating film 53. The tunnel insulating film 44 surrounds a portion of the side surface of the semiconductor film 42 excluding a contact surface with the insulating film 53. The charge storage film 45 surrounds a portion of the side surface of the tunnel insulating film 44 excluding a contact surface with the insulating film 53. The block insulating film 46 surrounds a portion of the side surface of the charge storage film 45 excluding a contact surface with the insulating film 53. The conductive layer 24 surrounds a portion of the side surface of the block insulating film 46 excluding a contact surface with the insulating film 53.

### 1.1.4.4 Planar Layout of Adjustment Region

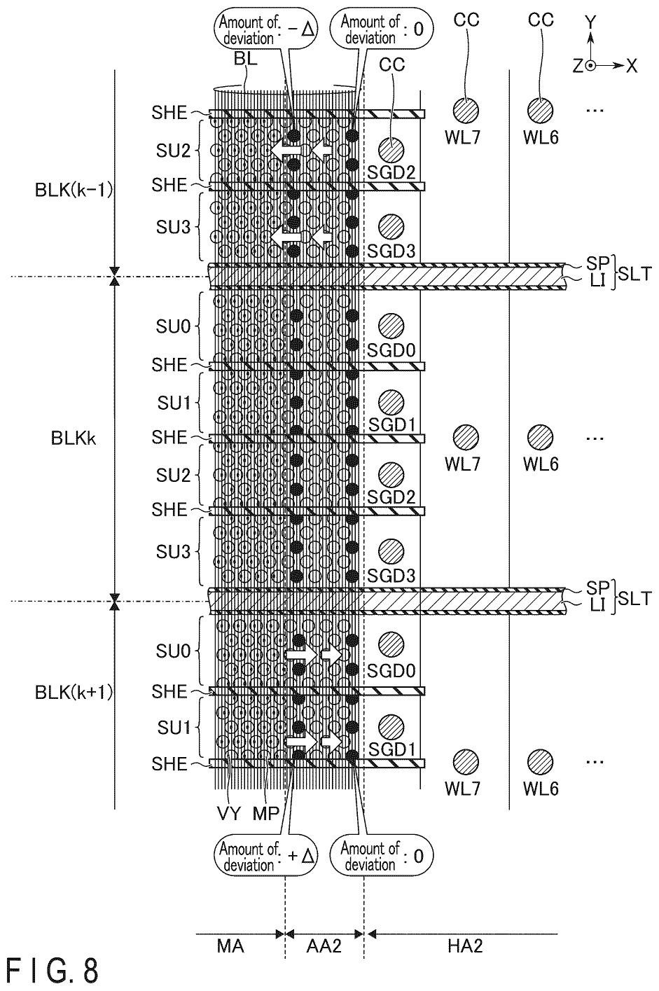

FIG. 8 is a plan view illustrating an example of a planar layout in the adjustment region of the memory cell array according to the embodiment. FIG. 8 illustrates the adjustment region AA2, a part of the memory region MA adjacent to the adjustment region AA2 in the X direction, and a part of the hookup region HA2. Although not illustrated in FIG. 8, the planar layout of the adjustment region AA1, the memory region MA adjacent to the adjustment region AA1 in the X direction, and the hookup region HA1 is the same as the planar layout of the adjustment region AA2, the memory region MA, and the hookup region HA2.

First, the planar layout of the hookup region HA2 will be described.

In the hookup region HA2, each of the select gate line SGS, the word lines WL0 to WL7, and the select gate line SGD includes a portion (terrace portion) of the stacked wiring that does not overlap with the upper wiring layers (conductive layers). In the hookup region HA2, the memory cell array 10 includes a plurality of contacts CC.

The shape of a portion of the hookup region HA2 that does not overlap with the upper wiring layers is similar to a step, a terrace, a rimstone, and the like. Specifically, steps are provided between the select gate line SGS and the word line WL0, between the word line WL0 and the word line WL1, . . . , between the word line WL6 and the word line WL7, and between the word line WL7 and the select gate line SGD. In the example of FIG. 8, a step is formed stepwise in the X direction at the ends of the terrace portions of the select gate line SGD and the word lines WL0 to WL7.

In the hookup region HA2, a plurality of contacts CC are provided on the respective terrace portions of the select gate line SGS, the word lines WL0 to WL7, and the select gate lines SGD0 to SGD3.

Each of the select gate line SGS, the word lines WL0 to WL7, and the select gate lines SGD0 to SGD3 is electrically connected to the row decoder module 15 via the corresponding contact CC. That is, for example, a voltage is applied to each of the select gate line SGS, the word lines WL0 to WL7, and the select gate lines SGD0 to SGD3 from the corresponding contact CC disposed in at least one of the hookup regions HA1 and HA2.

Next, the planar layout of the adjustment region AA2 will be described.

As described above, the planar layout of the memory pillar MP is shifted in the X direction by the pitch Δ of the bit lines BL between the adjacent blocks BLK. Therefore, at the boundary between the memory region MA and the adjustment region AA2, the amounts of deviation of the layouts of the memory pillars MP of the blocks BLK (k−1) and BLK (k+1) with respect to the block BLKk are −Δ and +Δ, respectively. In the adjustment region AA2, the memory pillar MP is disposed such that the amount of deviation between the blocks BLK becomes zero at the boundary between the adjustment region AA2 and the hookup region HA2.

That is, in the example of FIG. 8, in the adjustment region AA2 of the block BLK (k−1), the memory pillars MP are disposed such that the distance between the memory pillars MP aligned in the X direction is longer than the distance between the memory pillars MP aligned in the X direction in the adjustment region AA2 of the block BLKk. As a result, the amount of deviation −Δ occurring at the boundary between the memory region MA and the adjustment region AA2 gradually approaches zero as approaching the hookup region HA2. The amount of deviation can be regarded as zero at the boundary between the adjustment region AA2 and the hookup region HA2.

Similarly, in the adjustment region AA2 of the block BLK (k+1), the memory pillars MP are disposed such that the distance between the memory pillars MP aligned in the X direction is shorter than the distance between the memory pillars MP aligned in the X direction in the adjustment region AA2 of the block BLKk. As a result, the amount of deviation +Δ occurring at the boundary between the memory region MA and the adjustment region AA2 gradually approaches zero as approaching the hookup region HA2. The amount of deviation can be set to zero at the boundary between the adjustment region AA2 and the hookup region HA2. With the layout as described above, the start position of the hookup region HA2 can be prevented from being deviated in the X direction between the blocks BLK.

Note that the memory pillar MP disposed in the adjustment region AA2 is not used as the NAND string NS. Therefore, the contacts CH and VY are not provided on the upper surface of the memory pillar MP disposed in the adjustment region AA2. That is, the memory pillar MP disposed in the adjustment region AA2 is electrically insulated from the bit line BL.

### 1.2 Effects According to Embodiment

According to the embodiment, the plurality of memory pillars MP disposed in the blocks BLK (k+1) and BLK (k−1) are disposed to be deviated in the X direction with respect to the plurality of memory pillars MP disposed in the block BLKk. As a result, the parasitic capacitances of the bit lines BL can be leveled. The present effects will be described in detail below using comparative example.

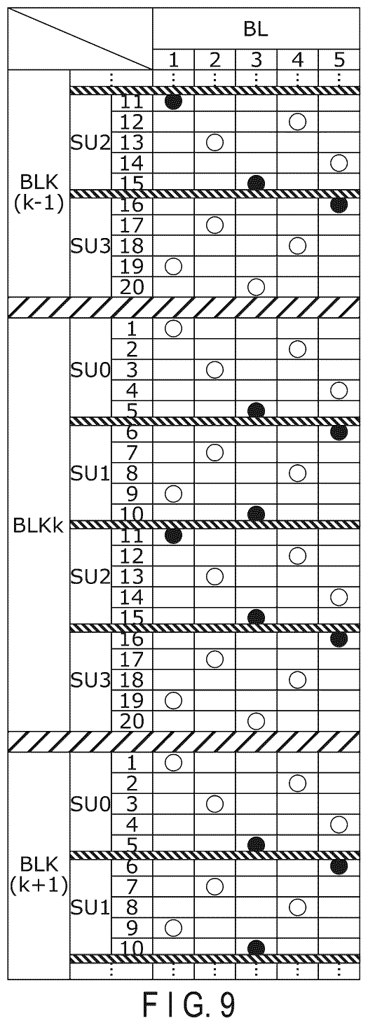

FIG. 9 is a diagram schematically illustrating an example of a connection relationship between a bit line and a memory pillar of a memory device according to comparative example. Comparative example corresponds to a case where the plurality of memory pillars MP disposed in the blocks BLK (k+1) and BLK (k−1) are not deviated in the X direction with respect to the plurality of memory pillars MP disposed in the block BLKk. In FIG. 9, the correspondence relationships between the five bit lines BL aligned continuously in the X direction and the row numbers of the memory pillars MP connected to the bit lines BL are indicated by circles. Among the memory pillars MP connected to the bit lines BL, the memory pillars MP not in contact with the member SHE and having a cylindrical shape are indicated by white circles. Meanwhile, the memory pillars MP having a shape in which a part of the cylinder is chipped by being in contact with the member SHE are indicated by black circles.

As illustrated in FIG. 9, in a case where the disposing of the plurality of memory pillars MP is not deviated in the X direction between the blocks BLK, the relationship between the memory pillar MP in contact with the member SHE and the corresponding bit line BL does not change between the blocks BLK. Therefore, the bit lines BL connected to the memory pillars MP in contact with the member SHE are concentrated on the first, third, and fifth bit lines BL (in particular, the third bit line BL) among the five bit lines BL. In other words, the memory pillar MP in contact with the member SHE is not connected to the second and fourth bit lines BL. As described above, in comparative example, a deviation occurs between the bit lines BL in the number of connections to the memory pillars MP having a shape in which a part of the cylinder is chipped.

In a case where a part of the memory pillar MP is chipped, the parasitic capacitance caused by the memory pillar MP viewed from the corresponding bit line BL changes. Therefore, in comparative example, a difference in parasitic capacitance occurs between the bit lines BL due to a difference in the number of connections to the memory pillars MP having a shape in which a part of the cylinder is chipped. The difference in parasitic capacitance leads to an increase in variation in data read time between the bit lines BL, which is not preferable.

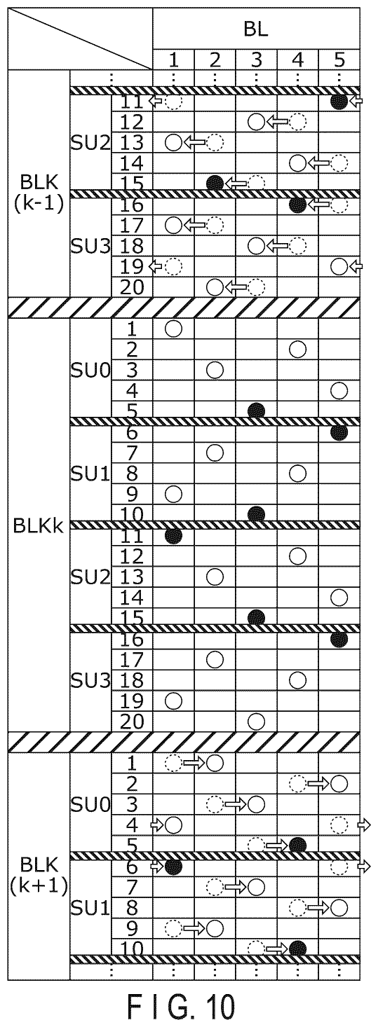

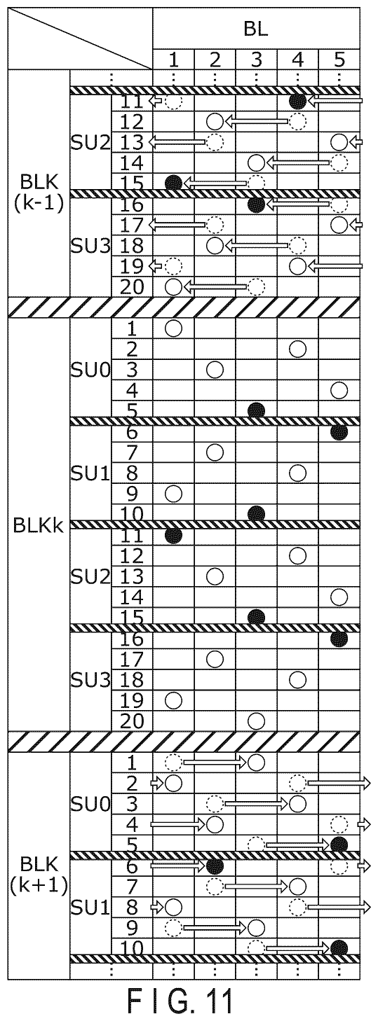

FIG. 10 is a diagram schematically illustrating an example of a connection relationship between a bit line and a memory pillar of the memory device according to the embodiment. FIG. 10 is a diagram in which FIG. 9 in comparative example corresponds to the embodiment. In FIG. 10, the portions indicated by the white circles or the black circles in comparative example of FIG. 9 are indicated by dotted circles. The deviations of the memory pillars MP in the X direction, occurring between comparative example and the embodiment are indicated by arrows.

As illustrated in FIG. 10, in a case where the disposing of the plurality of memory pillars MP is deviated in the X direction between the blocks BLK, the relationship between the memory pillar MP in contact with the member SHE and the corresponding bit line BL changes between the blocks BLK. Specifically, for example, in the block BLKk, the bit lines BL connected to the memory pillars MP in contact with the member SHE are concentrated on the first, third, and fifth bit lines BL among the five bit lines BL. In this case, in the block BLK (k−1), the bit lines BL connected to the memory pillars MP in contact with the member SHE are concentrated on the second, fourth, and fifth bit lines BL among the five bit lines BL. In the block BLK (k+1), the bit lines BL connected to the memory pillars MP in contact with the member SHE are concentrated on the first, (second), and fourth bit lines BL among the five bit lines BL. As a result, in the embodiment, the number of connections with the memory pillars MP having a shape in which a part of the cylinder is chipped can be leveled between the bit lines BL. Therefore, it is possible to reduce the difference in parasitic capacitance occurring between the bit lines BL due to the difference in the number of connections with the memory pillars MP having a shape in which a part of the cylinder is chipped. Therefore, it is possible to suppress variations in data read time among the bit lines BL.

The memory cell array 10 includes adjustment regions AA1 and AA2 between the memory region MA1 and the hookup regions HA1 and HA2. The deviation in the X direction of the disposing of the plurality of memory pillars MP between the blocks BLK occurring in the memory region MA is eliminated in the adjustment regions AA1 and AA2. As a result, the start position of the hookup region HA can be prevented from being deviated in the X direction between the blocks BLK. Therefore, it is possible to suppress an increase in the producing load of the hookup region HA due to the occurrence of the deviation of the disposing of the plurality of memory pillars MP between the blocks BLK.

### 2. MODIFICATION

Note that various modifications can be applied to the above-described embodiments.

### 2.1 First Modification

In the above-described embodiment, a case where the disposing of the plurality of memory pillars MP between the adjacent blocks BLK is deviated in the X direction by the pitch Δ of one bit line BL has been described, but the present invention is not limited thereto. For example, the disposing of the plurality of memory pillars MP between the adjacent blocks BLK may be an integral multiple of the pitch Δ of the bit line BL.

FIG. 11 is a diagram schematically illustrating an example of a connection relationship between a bit line and a memory pillar of a memory device according to a first modification. FIG. 11 corresponds to FIG. 10 in the embodiment. In the example of FIG. 11, a case where the disposing of the plurality of memory pillars MP between the adjacent blocks BLK is deviated in the X direction by a pitch 2A, which is twice of the pitch Δ of the bit lines BL, is illustrated.

As illustrated in FIG. 11, for example, in the block BLKk, the bit lines BL connected to the memory pillars MP in contact with the member SHE are concentrated on the first, third, and fifth bit lines BL among the five bit lines BL. In this case, in the block BLK (k−1), the bit lines BL connected to the memory pillars MP in contact with the member SHE are concentrated on the first, third, and fourth bit lines BL among the five bit lines BL. In the block BLK (k+1), the bit lines BL connected to the memory pillars MP in contact with the member SHE are concentrated on the second, (third), and fifth bit lines BL among the five bit lines BL. As a result, also in the first modification, similarly to the embodiment, the number of connections with the memory pillars MP having a shape in which a part of the cylinder is chipped can be leveled between the bit lines BL. Therefore, it is possible to reduce the difference in parasitic capacitance occurring between the bit lines BL due to the difference in the number of connections with the memory pillars MP having a shape in which a part of the cylinder is chipped. Therefore, it is possible to suppress variations in data read time among the bit lines BL.

### 2.2 Second Modification

In the above embodiment, a case where the region between any two adjacent members SLT in the Y direction is used as one block BLK has been described, but the present invention is not limited thereto. For example, a region between three or more members SLT continuously adjacent in the Y direction may be used as one block BLK.

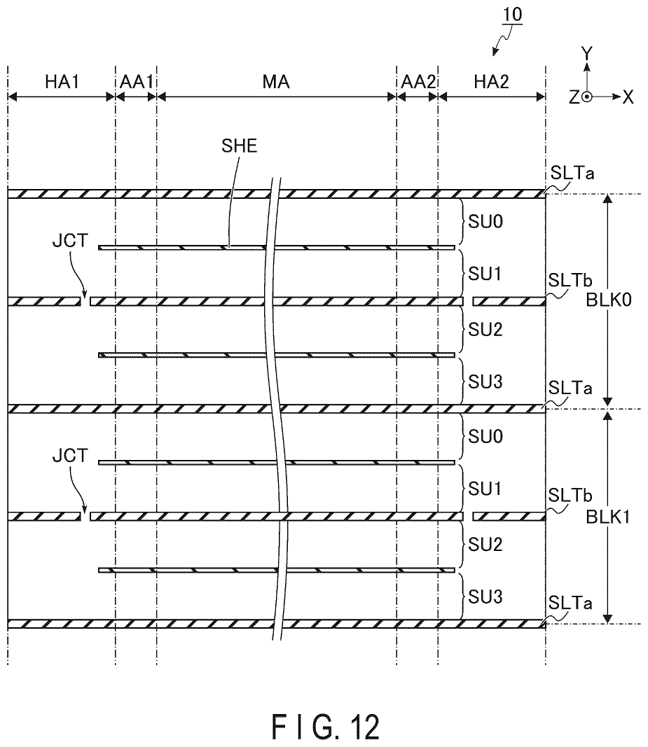

FIG. 12 is a plan view illustrating an example of a planar layout of a memory cell array included in a memory device according to a second modification. FIG. 12 corresponds to FIG. 3 in the embodiment. In the example of FIG. 12, a case where a region between three members SLT continuously adjacent in a Y direction is used as one block BLK is illustrated.

As illustrated in FIG. 12, each of the plurality of members SLT is classified into members SLTa and SLTb.

The member SLTa extends in an X direction over a memory region MA, adjustment regions AA1 and AA2, and hookup regions HA1 and HA2. That is, the member SLTa has the same configuration as that of the member SLT in the embodiment. Therefore, the stacked wiring structure is divided by the member SLTa. That is, the member SLTa functions as a boundary between the blocks BLK and electrically insulates the stacked wiring structures between the blocks BLK from each other.

The member SLTb extends in the X direction, but is disconnected in any of the memory region MA, the adjustment regions AA1 and AA2, and the hookup regions HA1 and HA2 (in the example of FIG. 12, the hookup regions HA1 and HA2). As a result, the stacked wiring structure is not completely divided by the member SLTb. Therefore, the stacked wiring structure includes a portion JCT connected in the Y direction at a portion where the member SLTb is disconnected. That is, the stacked wiring structures sandwiching the member SLTb are electrically connected via the portion JCT, and function as the same block BLK.

In the configuration of the memory cell array 10 including the members SLTa and SLTb as described above, the plurality of memory pillars MP disposed in one of any two adjacent blocks BLK with the member SLTa interposed therebetween are disposed to be deviated in the X direction with respect to the plurality of memory pillars MP disposed in the other block BLK. The plurality of memory pillars MP disposed in one of two portions in the same block BLK adjacent to each other with the member SLTb interposed therebetween are disposed to be deviated in the X direction with respect to the plurality of memory pillars MP interposed in the other portion. As a result, the connection relationship between the memory pillars MP and the bit lines BL can be leveled with the members SLTa and SLTb as boundaries, regardless of whether or not the connection relationship is the boundary between the blocks BLK. Therefore, as in the embodiment, the parasitic capacitances between the bit lines BL can be leveled.

### 2.3 Third Modification

In the above embodiment, a case where the memory cell array 10 has the planar layout in which two hookup regions sandwich one memory region has been described, but the present invention is not limited thereto. For example, the memory cell array 10 may have a planar layout in which two memory regions sandwich one hookup region.

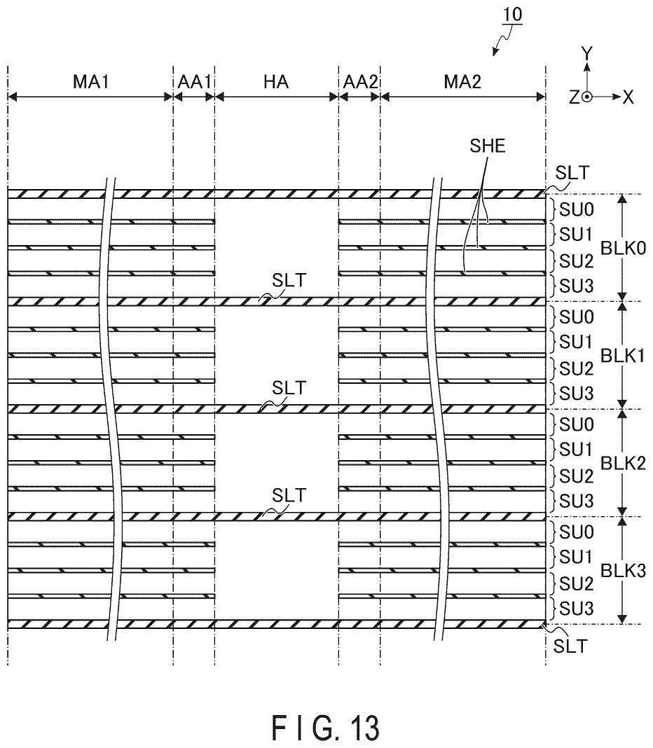

FIG. 13 is a plan view illustrating an example of a planar layout of a memory cell array included in a memory device according to a third modification. FIG. 13 corresponds to FIG. 3 in the embodiment. In the example of FIG. 13, a case where a memory cell array 10 is divided into memory regions MA1 and MA2, adjustment regions AA1 and AA2, and a hookup region HA in a X direction is illustrated.

As illustrated in FIG. 13, the hookup region HA is disposed, for example, in the central portion of the memory cell array 10. The adjustment regions AA1 and AA2 are disposed so as to sandwich the hookup region HA in the X direction. The memory regions MA1 and MA2 are disposed so as to sandwich the adjustment region AA1, the hookup region HA, and the adjustment region AA2 in the X direction. In the example of FIG. 13, a case where the memory region MA1, the adjustment region AA1, the hookup region HA, the adjustment region AA2, and the memory region MA2 are aligned in this order in the X direction is illustrated.

In the planar layout of the memory cell array 10 as described above, the plurality of memory pillars MP disposed in the blocks BLK (k+1) and BLK (k−1) are disposed to be deviated in the X direction with respect to the plurality of memory pillars MP disposed in the block BLKk. As a result, as in the embodiment, the parasitic capacitances of the bit lines BL can be leveled.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a plurality of first conductive layers aligned apart from each other in a first direction;
a first member extending in a second direction intersecting the first direction and dividing the first conductive layers into a first portion and a second portion aligned in a third direction intersecting the first direction and the second direction;
a plurality of first memory pillars each extending in the first direction and intersecting with each of the first portions of the first conductive layers; and
a plurality of second memory pillars each extending in the first direction and intersecting with each of the second portions of the first conductive layers,
wherein the second memory pillars are disposed to be deviated with respect to the first memory pillars in the second direction as viewed in the first direction.

2. The memory device according to claim 1, further comprising a plurality of bit lines connected to the first memory pillars and the second memory pillars,
wherein an amount of deviation of disposing of the second memory pillars with respect to disposing of the first memory pillars in the second direction is an integral multiple of a pitch of the bit lines in the second direction.

3. The memory device according to claim 2, further comprising a second member extending in the second direction and dividing the first portion of a third conductive layer included in the first conductive layers into a first sub-portion and a second sub-portion aligned in the third direction,
wherein the first memory pillars include a third memory pillar being in contact with the second member and a fourth memory pillar being not in contact with the second member.

4. The memory device according to claim 3,
wherein, as viewed in the first direction, a shape of the third memory pillar is different from a shape of the fourth memory pillar at a position of the third conductive layer in the first direction.

5. The memory device according to claim 3, further comprising a third member extending in the second direction and dividing the second portion of the third conductive layer into a third sub-portion and a fourth sub-portion aligned in the third direction,
wherein the second memory pillars include a fifth memory pillar being in contact with the third member and a fifth memory pillar being not in contact with the third member, and
the third memory pillar and the fifth memory pillar are connected to bit lines different from each other among the bit lines.

6. The memory device according to claim 5,
wherein, as viewed in the first direction, the first conductive layers include:
a first region in which the first memory pillars and the second memory pillars are provided; and
a second region in which terrace portions each of which does not overlap with an upper first conductive layer are provided, the second region being aligned with the first region in the second direction, and
a disposing deviation in the second direction between the first memory pillars and the second memory pillars is eliminated in a boundary region between the first region and the second region.

7. The memory device according to claim 6, further comprising:
a first contact electrically connected to the terrace portion of the first sub-portion of the third conductive layer; and
a second contact electrically connected to the terrace portion of the second sub-portion of the third conductive layer.

8. The memory device according to claim 7, further comprising a plurality of third contacts electrically connected to the terrace portions of conductive layers excluding the third conductive layer among the first conductive layers, respectively.

9. The memory device according to claim 1,
wherein the first portion of the first conductive layers is electrically insulated from the second portion of the first conductive layers by the first member.

10. The memory device according to claim 9,
wherein data stored in the first memory pillars is simultaneously erased, and
data stored in the second memory pillars is simultaneously erased at a timing different from that of the data stored in the first memory pillars.

11. The memory device according to claim 1,
wherein the first conductive layers further include a third portion electrically connecting the first portion and the second portion to each other.

12. The memory device according to claim 11,
wherein data stored in the first memory pillars and data stored in the second memory pillars are simultaneously erased.
